(19) United States
(12) Patent Application Publication
(10) Pub. No.: US 2001/0048298 A1
(43) Pub. Date: Dec. 6, 2001

(54) Method and apparatus for analyzing noise in a digital circuit, and storage medium storing an analysis program

(75) Inventors: Kazuyuki Doshita, Takefu-shi (JP); Nobuhiko Kawai, Omihachiman-shi (JP); Tsutomu Okada, Shiga-ken (JP)

Correspondence Address: OSTROLENK FABER GERB & SOFFEN, 1180 AVENUE OF THE AMERICAS, NEW YORK, NY, 100368403

(73) Assignee: Murata Manufacturing Co. , Ltd.

(21) Appl. No.: 09/815,879

(22) Filed: Mar. 22, 2001

(30) Foreign Application Priority Data
Mar. 22, 2000 (JP) 2000-80556

(51) Int. Cl. G01R 23/16

(52) U.S. Cl. 324/76.21

(57) ABSTRACT

A method for simulating noise in a digital circuit allows a quick simulation using an ordinary personal computer installed with reasonably-priced software. When the program is activated, a screen appears on a display to permit settings to be inputted to specify a circuit to be simulated. The input screen has an input signal specifying section, a transmitter IC specifying section, a filter specifying section, a transmission line specifying section, and a receiver IC specifying section, whereby the transfer function of the simulated circuit is obtained. An input signal is Fourier-expanded, and a frequency-domain output spectrum is obtained from the transfer function and the Fourier-expanded input signal. Then, the frequency-domain output spectrum is inversely Fourier-expanded to obtain a time-domain output waveform.

### BACKGROUND OF THE INVENTION

1. Field of the Invention

The present invention relates to a method and an apparatus for analyzing noise in a digital circuit. In particular, the present invention is concerned with a method and apparatus for analyzing noise generated in a digital circuit incorporating digital ICs, and also to a storage medium storing an analysis program.

2. Description of the Related Art

In digital circuits incorporating digital ICs, filters are commonly used to exclude noise generated within the digital circuits, which may affect other electronic devices. It has not been easy, however, to select a filter, since the filter must match both the particular digital ICs, and the circuit boards on which the digital ICs are mounted, having different characteristics from one another. Accordingly, in order to analyze noise in a digital circuit and to thereby facilitate selection of an appropriate noise filter, a method has been proposed in which an input signal of a digital circuit is divided in the time domain and a corresponding output signal is computed for each of the divided time steps.

Although the conventional method allows precise analysis, the method requires computations for a lot of time steps before reaching a steady state, and also requires complex and sophisticated computations to obtain the relevant characteristics of the digital ICs. Therefore, the method requires the use of a high-end computer and expensive software, raising the relevant cost. On the other hand, if an ordinary personal computer were used, the analysis would take too long.

### SUMMARY OF THE INVENTION

Accordingly, the present invention provides a method of analyzing noise in a digital circuit by performing a simulation, which enables quick analysis using an ordinary personal computer running reasonably priced software.

The present invention also provides an apparatus for analyzing noise in a digital circuit, which employs software to perform noise simulations with ease.

The present invention further provides a storage medium storing such software.

To these ends, the present invention in one aspect provides a method for analyzing noise in a digital circuit of the type that has a digital IC, a passive circuit, and a transmission line. The method includes the steps of obtaining the transfer function of the digital circuit from the circuit constants of an equivalent circuit of the digital IC constituted of passive components, the circuit constants of the passive circuit, and the circuit constants of the transmission line; expanding an input signal to the digital circuit into a sine-wave series by Fourier expansion; obtaining a frequency-domain output spectrum of the digital circuit from the transfer function of the digital circuit and the sine-wave series; and transforming the frequency-domain output spectrum into a time-domain output waveform by inverse Fourier transformation.

The present invention in another aspect provides an apparatus for analyzing noise in a digital circuit of the type that incorporates a digital IC, a passive circuit, and a transmission line. The apparatus includes a first input device for inputting the circuit constants of an equivalent circuit of the digital IC constituted of passive components;

a second input device for inputting the circuit constants of the passive circuit; a third input device for inputting the circuit constants of the transmission line; a first operation unit for obtaining the transfer function of the digital circuit from the circuit constants of the equivalent circuit of the digital IC constituted of passive components, the circuit constants of the passive circuit, and the circuit constants of the transmission line; a second operation unit for expanding an input signal to the digital circuit into a series of sine waves by Fourier expansion; a third operation unit for obtaining a frequency-domain output spectrum of the digital circuit from the transfer function of the digital circuit and the series of sine waves; and a fourth operation unit for transforming the frequency-domain output spectrum into a time-domain output waveform by inverse Fourier transformation.

In accordance with the present invention, the Fourier expansion of an input signal permits the latter to be expressed in terms of a sum of a series of sine waves. Transformation or reduction of a digital IC, which is a non-linear component, into an equivalent circuit composed of passive components permits a circuit analysis by a simple linear computation, without requiring complicated non-linear computations to determine the characteristics of an IC. More specifically, the transfer function of a digital circuit can be determined based on the circuit constants of the digital IC equivalent circuit and on the circuit constants of the passive components and the transmission line. It is possible to obtain a frequency-domain output spectrum, based on the transfer function and the Fourier-expanded input signal. It is therefore possible to obtain a time-domain output waveform, through an inverse Fourier transformation of the frequency-domain output spectrum.

The noise analysis method of the present invention may be implemented by a program which performs noise analysis in accordance with the described procedure. The transfer function of the digital circuit can be determined simply by inputting the circuit constants. This enables computation of output signals for a variety of input signals and, hence, for a variety of classes of components. This makes it possible to select an optimum filter, based on an output waveform obtained when such a filter is incorporated in the digital circuit.

The apparatus may include a first storing device for storing the circuit constants for respective equivalent circuits of a plurality of digital ICs, whereby the circuit constants of a digital IC selected from the plurality of digital ICs may be read out from the first storing device and input to the first operation unit. This eliminates the need to enter the circuit constants individually.

The apparatus may also include a calculation device for calculating the circuit constants of the transmission line based on factors including the line width and line length of a pattern formed on a wiring board, circuit board thickness, and substrate material, whereby the calculated circuit constants may be input to the first operation unit. This allows the user to enter the characteristic values instead of calculating the circuit constants manually.

The apparatus may also include a second storing device for storing the circuit constants of a plurality of passive circuits, whereby the circuit constants of a passive circuit selected from the plurality of passive circuits may be read out from the second storing device to be input to the first operation unit. By storing the circuit constants of, for example, noise filters, the effects of the filters can be simulated without entering the circuit constants of the filters individually.

Preferably, the apparatus includes a display for displaying passive circuit characteristics when selecting one of the plurality of passive circuits, so that the passive circuit characteristics information is available when selecting a desired passive circuit.

It is preferable that the frequency-domain output spectrum obtained by the third operation unit and the time-domain output waveform obtained by the fourth operation unit are displayed on the display, thus enabling confirmation of the results of the analysis.

It is also preferable that the impedance-frequency characteristics of the digital circuit are displayed on the display.

It is also preferable that the results of operations performed with different transfer functions are simultaneously displayed on the display, so that the analysis results can readily be compared.

The device may also include a printing device for simultaneously printing input information regarding the transfer function of the digital circuit, and the results of simulation, so that the analysis results can be reviewed in association with the conditions of the analysis.

The present invention, in still another aspect thereof, provides a storage medium storing a program. The program includes the steps of obtaining the transfer function of the digital circuit from the circuit constants of an equivalent circuit of the digital IC constituted of passive components, the circuit constants of the passive circuit, and the circuit constants of the transmission line; expanding an input signal to the digital circuit into a series of sine waves by Fourier expansion; obtaining a frequency-domain output spectrum of the digital circuit from the transfer function of the digital circuit and the series of sine waves; and transforming the frequency-domain output spectrum into a time-domain output waveform by inverse Fourier transform. By installing the program on a computer from the storage medium, the computer can be used as a noise analyzer for digital circuits.

The invention further relates to a method of enabling a user to select a passive circuit, the passive circuit being included in a digital circuit along with a digital IC and a transmission line, the method comprising the steps of: supplying the user with a program for analyzing noise in the digital circuit, on the basis of circuit constants of the digital IC, the transmission line, and the passive circuit; and supplying the user with circuit constants of a plurality of passive circuits, thereby enabling the user to select a passive circuit from among the plurality of passive circuits on the basis of an analysis result of said program.

The above and other features and advantages of the present invention will become apparent from the following description of embodiments of the invention taken in conjunction with the accompanying drawings.

### BRIEF DESCRIPTION OF THE DRAWINGS

FIG. 1 shows an initial screen which appears upon activation of an apparatus for analyzing noise in a digital circuit according to an embodiment of the present invention;

FIG. 2 shows a screen prompting a user to enter circuit constants of a transmitter IC and a receiver IC;

FIG. 3 shows a window for enabling the user to select a filter;

FIG. 4 is a diagram showing a relationship between a wiring board and a transmission line fabricated thereon;

FIG. 5 shows a screen which appears when a plurality of input settings have been entered;

FIG. 6 shows a screen displaying analysis results; and

FIG. 7 shows a screen displaying results of a plurality of analyses performed with different settings; and

FIG. 8 shows a printout of analysis results.

### DESCRIPTION OF EMBODIMENTS OF THE INVENTION

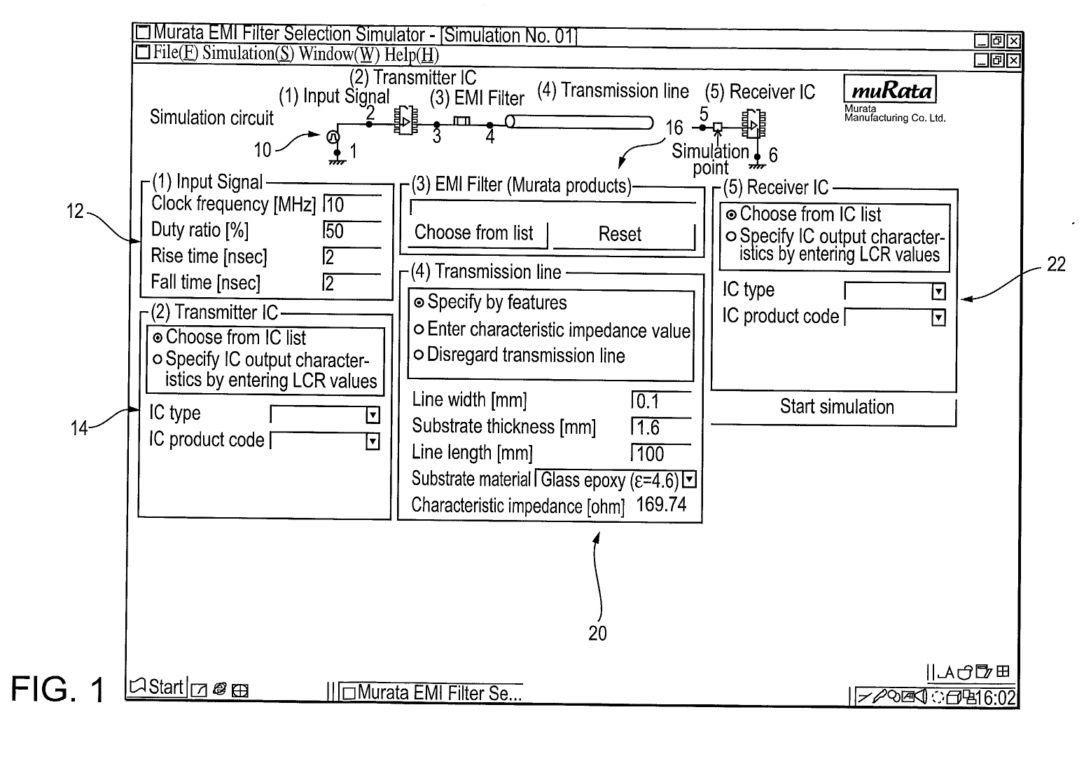

FIG. 1 shows an initial screen appearing on a display connected to a noise analyzing apparatus according to the present invention. By way of example, the noise analyzing apparatus may be a personal computer installed with a program for implementing a noise analyzing method according to the present invention. When the program is activated, the initial screen as shown in FIG. 1 appears. Shown at the top of the screen is a circuit diagram of a simulation circuit 10. The noise analyzing apparatus is used for analyzing noise in a digital circuit incorporating digital Ics. Digital ICs can be provided to perform a variety of circuit functions, such as transmitting, receiving, amplification and/or signal processing. The circuit diagram shows an input signal (1), a transmitter IC (2), a passive circuit (3), a transmission line (4), a receiver IC (5), and a simulation point, which is the location in the simulated circuit where the simulated output wave form exists. In the illustrated embodiment, the passive circuit is a noise filter, and the transmission line is a wiring board on which the digital ICs are mounted.

The upper left of the screen is an input signal specifying section 12, in which the input signal is specified in terms of clock frequency, duty ratio, and rise time and fall time. These characteristic values of the input signal are entered via an input device, for example, a keyboard.

In the lower left of the screen is a transmitter IC specifying section 14. The transmitter IC is either selected from a list of ICs via an input device, for example, a mouse, or specified by entering IC values of inductance, capacitance, and resistance via an input device, for example, a keyboard.

For the settings in the transmitter IC specifying section 14, a variety of digital ICs have been transformed into the form of equivalent LCR circuits composed of passive elements. That is, the values of inductance, capacitance, and resistance for each of a plurality of LCR circuits transformed from a variety of digital ICs are stored in a storage medium such as a memory or a hard disk. Thus, once a digital IC to be used is selected from the list, the values of inductance, capacitance, and resistance for an equivalent LCR circuit of the digital IC are automatically read from the storage medium to be entered in the corresponding boxes.

In selecting a digital IC, initially a choice is made between CMOS IC and TTL IC in the IC type box. When CMOs IC is chosen, product codes of CMOS ICs are displayed in the product code box, so that the user can select one of the CMOS ICs. When TTL IC is chosen, one of the TTL ICs is selected in a similar manner.

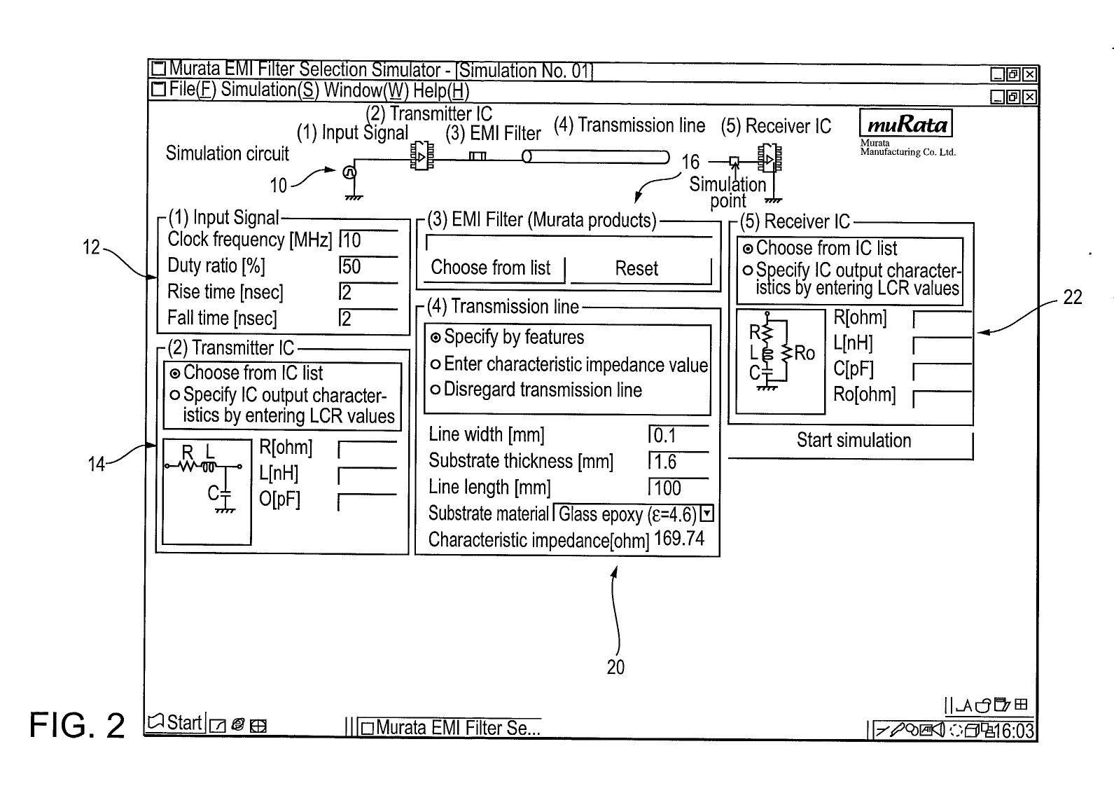

When the user has chosen on the transmitter IC setting section 14 to enter the output characteristics of an IC in terms of LCR, an LCR circuit transformed from the digital IC is displayed as shown in FIG. 2, thus permitting values of the inductance, capacitance and resistance to be entered individually.

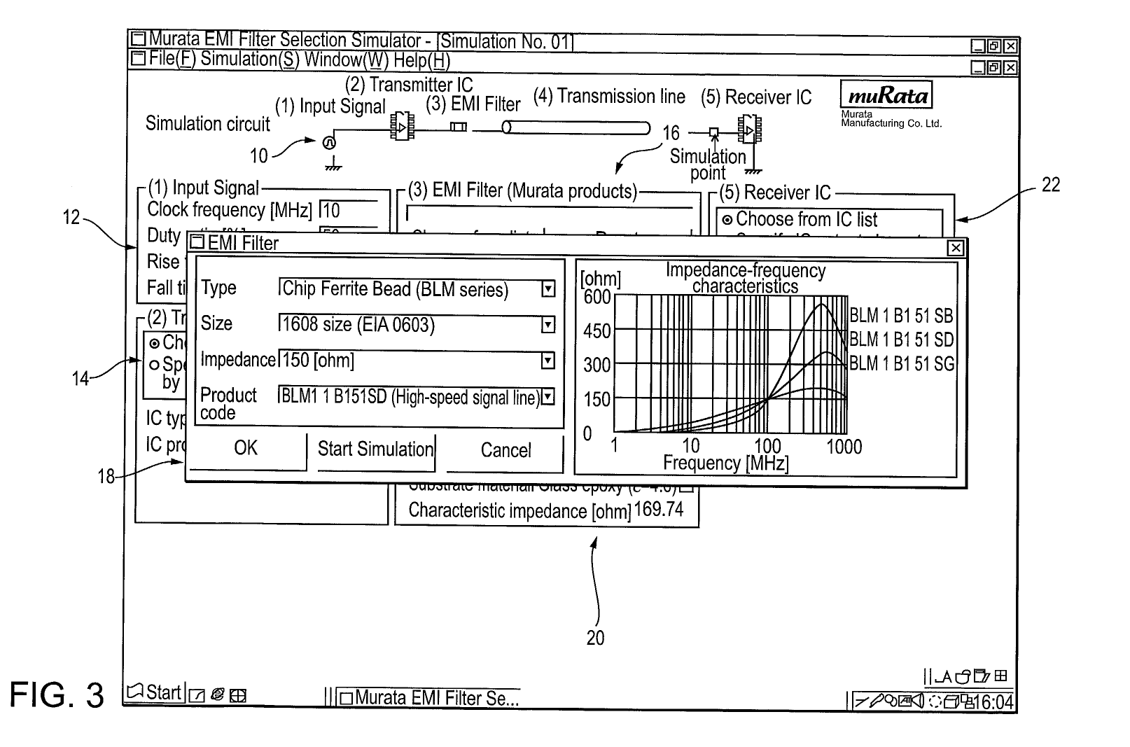

At the center of the screen is a filter specifying section 16 for specifying a filter, which is a passive circuit, in which a filter is selected from a list of filters stored in a storage medium. As shown in FIG. 3, a window 18 for enabling selection of a filter is activated. In the window 18, the user selects the filter type such as the chip ferrite bead type, the filter size, and the filter impedance, in that order. The window 18 includes boxes for macro-, medium-, and micro-classifications, as well as a product code box. The macro-classification box is used to enable the user to select the type of the desired filter, e.g., a chip-ferrite bead filter. The medium-classification box is used for selection of the size of the filter of the type specified in the macro-classification box, while the micro-classification box permits selection of the impedance of the selected filter. When a plurality of filters match the specified characteristics, the impedance-frequency characteristics for each of the plurality of filters are Too displayed, together with the product code of the filter. Then, a desired filter is selected by examining the characteristics of the plurality of filters.

In the lower center of the screen is a transmission line specifying section 20, which permits settings of the characteristic impedance of a wiring board on which the digital ICs are to be mounted. The characteristic impedance is calculated from the line length and line width of a pattern fabricated on a substrate, and the thickness and material of the substrate. More specifically, the characteristic impedance Z and the propagation constant β of the transmission line are expressed, respectively, by the following equations 1 and 2, where l represents the line length.

$$Z = \frac{60}{\sqrt{{ϵ}_{ef}}} ln [ f \frac{h}{{W}_{0}} + \sqrt{1 + {( 2 h / {W}_{0} )}^{2}} ] \qquad ( 1 )$$

β=ω\sqrt{ε_{ef}}/c₀ (2)

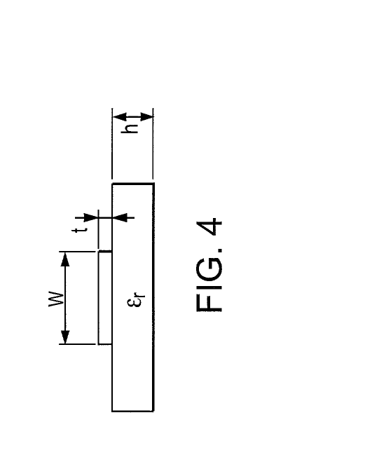

The constants ε_{ef}, f, and W₀ are expressed, respectively, by the following equations 3, 4, and 5. As shown in FIG. 4, h is the thickness of the substrate, W is the electrode width, t is the electrode thickness, εᵣ is the relative dielectric constant of the substrate, and cₒ is the velocity of light in vacuum.

$${ϵ}_{ef} = \frac{{ϵ}_{r} + 1}{2} + \frac{{ϵ}_{r} - 1}{2} {( 1 + 10 h / W )}^{- 1 / 2} \qquad ( 3 )$$

f=6+0.283exp[−(30.7h/W₀)^{0.753}] (4)

$${W}_{0} = W + \frac{t}{π} ln \frac{4 e}{\sqrt{{( t / h )}^{2} + \frac{1}{{{π}^{2} ( W / t + 1.1 )}^{2}}}} \qquad ( 5 )$$

As described, by incorporating a program for calculating the characteristic impedance of the transmission line from the line length, line width, substrate thickness, and substrate material, the characteristic impedance can readily be specified and entered.

In addition, there may be a user-selectable mode for enabling manual entry of a characteristic impedance which for example may be calculated by the user.

Further, it is also possible to arrange for the transmission line to be disregarded. In such a case, the noise analysis is performed on the assumption that there is no impedance component attributable to the transmission line.

On the right side of the screen is a receiver IC specifying section 22, in which IC type and IC product code can be selected in a similar manner as in the transmitter IC specifying section 14. When the user chooses to specify input characteristics by entering the values of inductance, capacitance, and resistance, an LCR circuit is displayed with boxes to enter those values individually, as shown in FIG. 2.

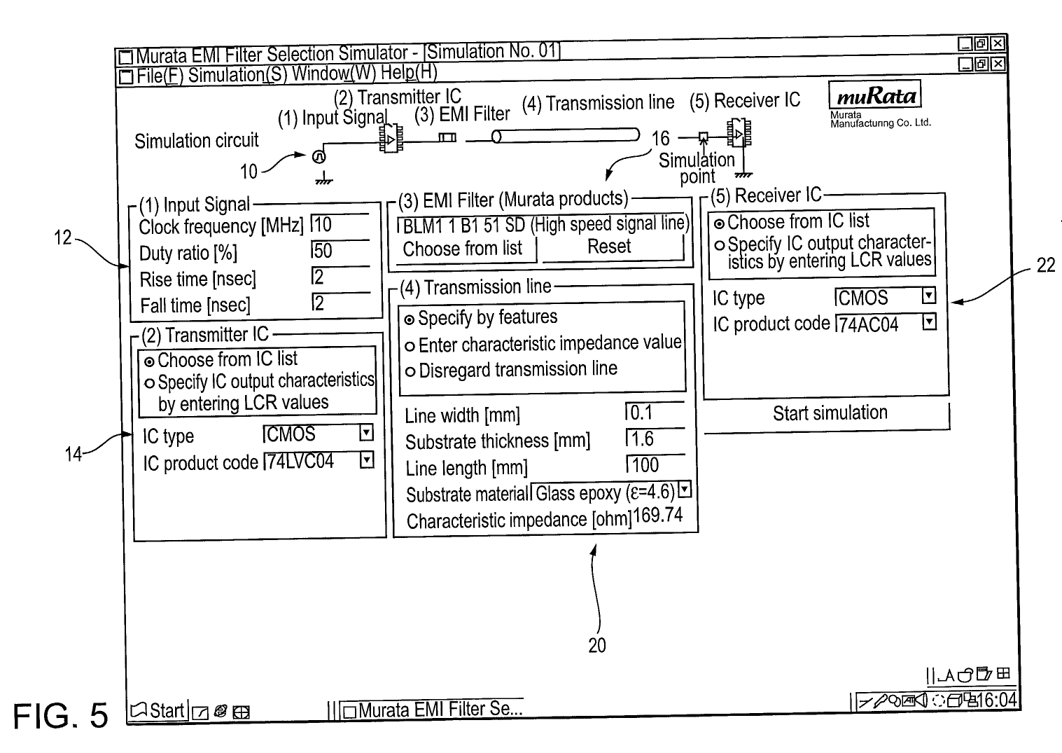

When the settings are complete as shown in FIG. 5, the “Start simulation” button is clicked on to start the noise analysis. First, the transfer function of the digital circuit is calculated. A two-terminal circuit component can be described by a 2×2 admittance matrix y as expressed in the following equation (6).

$$y = [ \begin{matrix}{y}_{11} & {y}_{12} \\ {y}_{21} & {y}_{22}\end{matrix} ] \qquad ( 6 )$$

The admittance matrices for all the circuit components are summed. The following equation (7) expresses an example where a component A is connected between node 2 and node 3, and a component B is connected between node 3 and node 4 (junction points between the above-described circuit components are shown in FIG. 1 as nodes 1, 2, 3, 4, 5 and 6).

$$[ \begin{matrix}0 & 0 & 0 & 0 & ⋯ \\ 0 & {y}_{11}^{A} & {y}_{12}^{A} & 0 & ⋯ \\ 0 & {y}_{21}^{A} & {y}_{22}^{A} + {y}_{11}^{B} & {y}_{12}^{B} & ⋯ \\ 0 & 0 & {y}_{21}^{B} & {y}_{22}^{B} & ⋯ \\ ⋮ & ⋮ & ⋮ & ⋮ & ⋰\end{matrix} ] [ \begin{matrix}{V}_{1} \\ {V}_{2} \\ {V}_{3} \\ {V}_{4} \\ ⋮\end{matrix} ] = [ \begin{matrix}{I}_{1} \\ {I}_{2} \\ {I}_{3} \\ {I}_{4} \\ ⋮\end{matrix} ] \qquad ( 7 )$$

The transfer function of the simulation circuit 10 is obtained by summing the admittance matrices as above based on the settings of the components for all the components included in the simulation circuit 10. The admittance matrices of a resistor, a capacitor, an inductor, a transmission line, and a custom component, are expressed by, respectively, equations (8), (9), (10), (11), and (12). In equation (11), the characteristic impedance Z is obtained by equation (1), and the propagation constant β is obtained by equation (2). The custom component expressed by equation (12) is a digital IC herein.

$$\begin{matrix}y = [ \begin{matrix}1 / R & - 1 / R \\ - 1 / R & 1 / R\end{matrix} ] & ( 8 ) \\ y = [ \begin{matrix}j ω C & - j ω C \\ - j ω C & j ω C\end{matrix} ] & ( 9 ) \\ y = [ \begin{matrix}1 / j ω L & - 1 / j ω L \\ - 1 / j ω L & 1 / j ω L\end{matrix} ] & ( 10 ) \\ y = \frac{1}{jZ sin β 1} [ \begin{matrix}cos β1 & - 1 \\ - 1 & cos β1\end{matrix} ] & ( 11 ) \\ y = [ \begin{matrix}1 / Z ( ω ) & - 1 / Z ( ω ) \\ - 1 / Z ( ω ) & 1 / Z ( ω )\end{matrix} ] & ( 12 )\end{matrix}$$

When the transfer function of the simulation circuit 10 is obtained, then the input signal is Fourier-expanded. That is, the time-domain input signal is reduced to a frequency-domain sine wave series, thereby enabling frequency response analysis. For instance, if Vᵢₙ(t), an input voltage at time t, cyclically varies with a period T, Vᵢₙ(t) can be approximated by a series of N sine waves as expressed in the following equations (13).

$${V}_{in} ( t ) ≅ {\sum }_{n = 0}^{N} {c}_{n} exp ( j {ω}_{n} t ) , {ω}_{n} ≡ 2 π n / T \qquad ( 13 )$$

In the above equation (13), Cₙ is the magnitude of the angular frequency ωₙ component of the input signal. The output voltage F[cₙexp(jωₙt)] corresponding to the component can readily be obtained by an ordinary circuit calculation using the previously obtained transfer function of the digital circuit. The amplitude Fₙ is expressed by the following equation (14).

F[cₙexp(jωₙt)]=Fₙexp(ωₙt) (14)

From the above equation (14), a voltage spectrum represented in the frequency domain is obtained. Then, the frequency-domain voltage spectrum is transformed into a time-domain output voltage vₒᵤₜ(t) waveform by inverse Fourier transform, as expressed by the following equation (15).

$${V}_{out} ( t ) = {\sum }_{n = 0}^{N} {F}_{n} exp ( j {ω}_{n} t ) \qquad ( 15 )$$

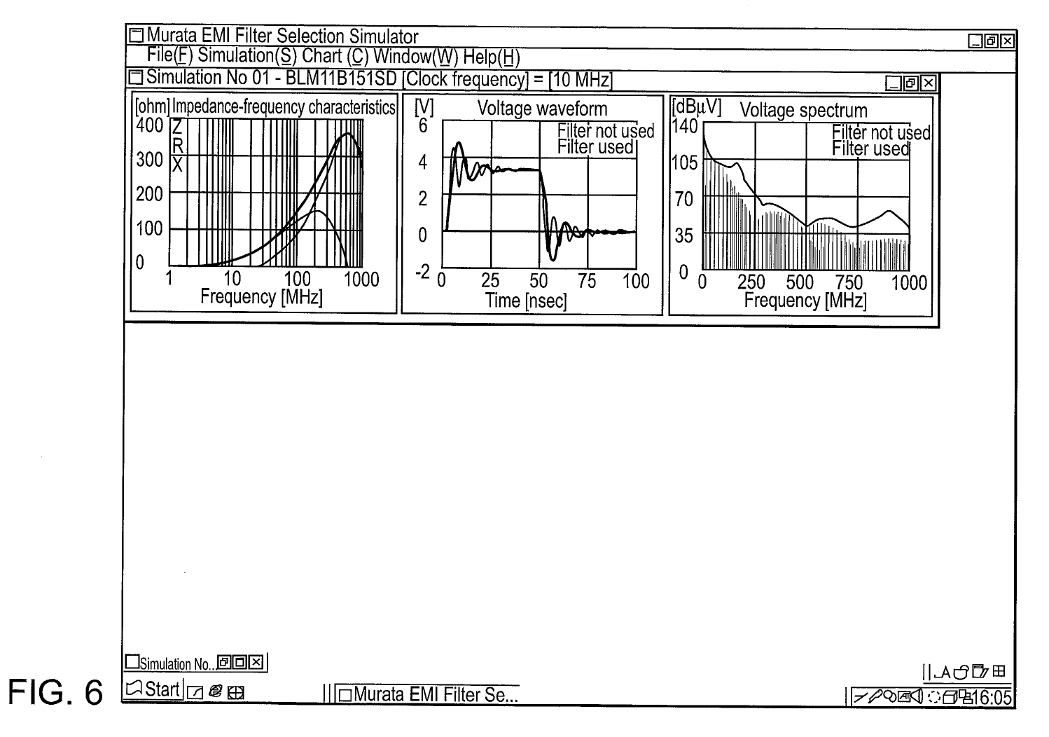

The output voltage thus obtained as the analysis result is expressed on the screen by the frequency-domain voltage spectrum and the time-domain voltage waveform, as shown in FIG. 6. Furthermore, the output voltage waveform is simulated and displayed both for the case where the filter is used and the case where the filter is not used, so that the effect of the filter is well understood. Also shown on the screen are the impedance-frequency characteristics of the digital circuit. Based on the simulation results, a filter which provides desired output characteristics can be selected.

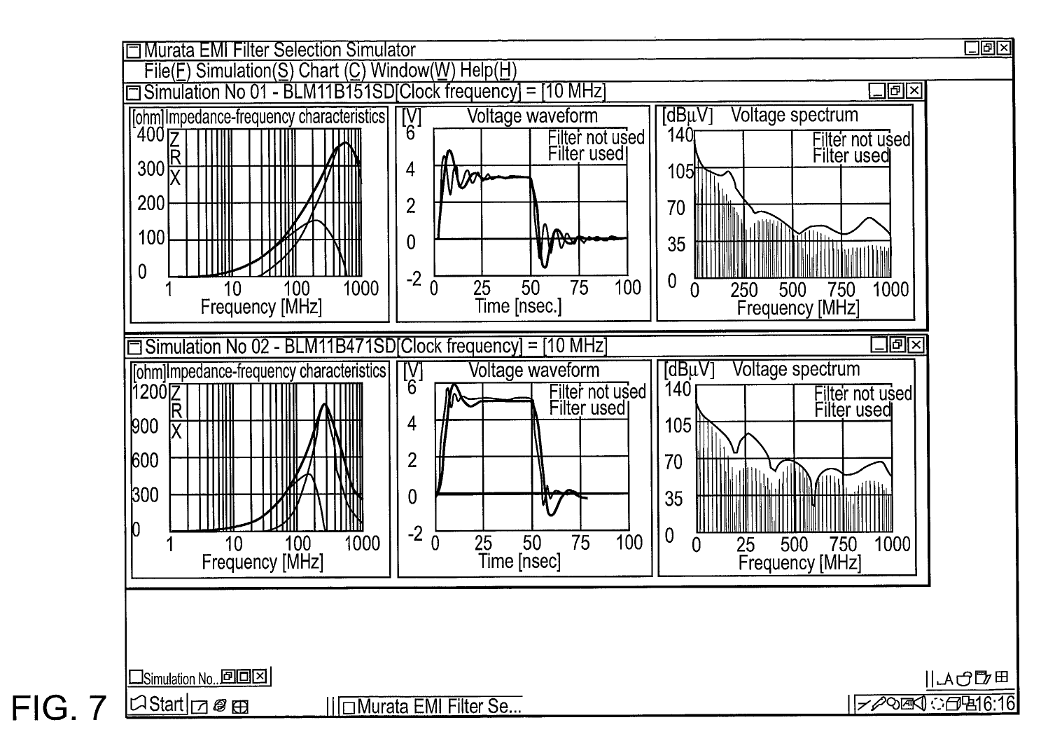

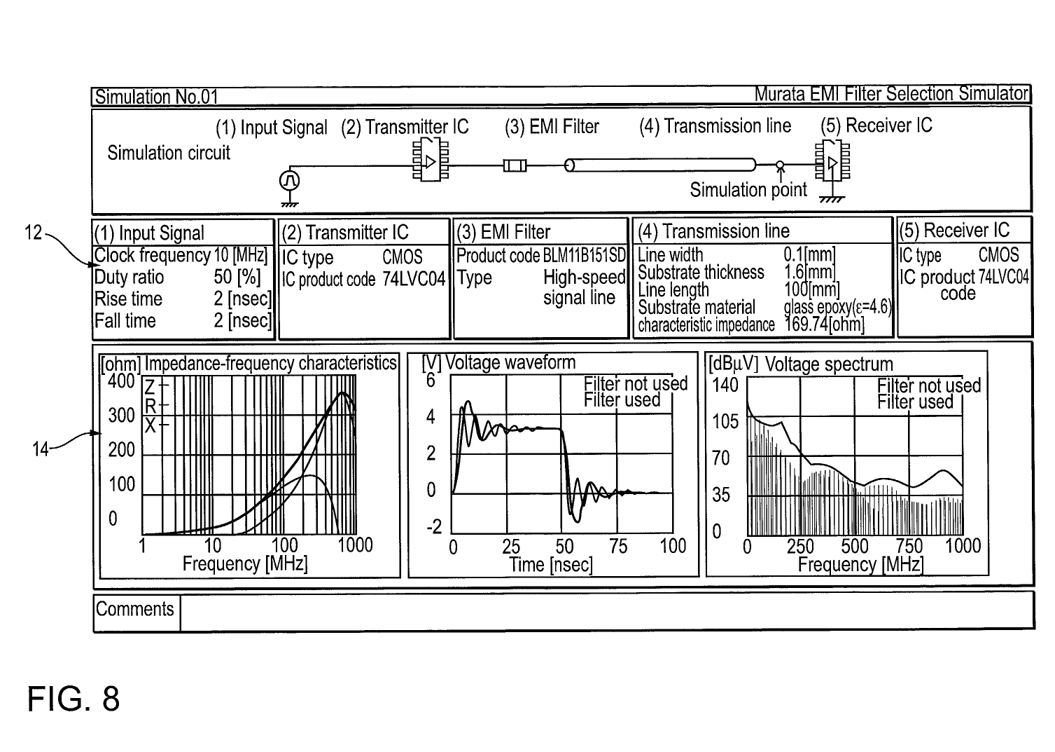

It is preferable for the results of a plurality of simulations obtained with a variety of set values to be simultaneously displayed on one screen, as shown in FIG. 7, so that output waveforms provided by different filters can readily be compared. It is also preferable for the results to be printed out via a printer as shown in FIG. 8 so that the results can be used for later examination. Furthermore, the printout may include the simulation settings as well as the simulation results, so that the settings and the results can be correlated.

The noise analysis method as described above allows batch processing and therefore quick calculation, as opposed to the conventional method in which the input signal is divided into a large number of time steps and the calculation is repeated for the successive time steps. In addition, the described noise analysis method can be implemented by a simpler program than the conventional method, and thus can be used on an ordinary personal computer.

Such a program for implementing a noise analysis method according to the present invention may be stored on a storage medium, for example, a CD-ROM, for being installed on a personal computer. Alternatively, the program may be downloaded from a website. In either case, the personal computer on which the program is installed works as a noise analyzing apparatus according to the present invention.

Sales of filter products can be promoted by distributing the program to prospective filter customers, by allowing downloading from a web site or by means of CD-ROMs, for example. To this end, the filter setting section 16 is arranged for selection of the filter products of the program distributor, such as the filter manufacturer, to enable s potential purchasers to use the noise analyzing method when considering whether to purchase those filter products. Thus, the use of the analysis program on the stored data concerning the manufacturer's filters provides customer with information concerning the output waveforms obtainable with and without each such filter, which naturally drives the customers to purchase those filters. A purchaser also can enjoy the advantage of having a chance to confirm the output waveform before placing a purchase order.

Although the invention has been described in connection with embodiments thereof, it is to be understood that the described embodiments are only illustrative and various changes and modifications may be imparted thereto without departing from the scope of the present invention.

What is claimed is:

1. A method for analyzing noise in a digital circuit which incorporates a digital IC, a passive circuit, and a transmission line, said method comprising the steps of:
obtaining the transfer function of said digital circuit based on the circuit constants of an equivalent circuit of said digital IC constituted of passive components; the circuit constants of said passive circuit; and the circuit constants of said transmission line;
expanding an input signal to be supplied to said digital circuit into a sine wave series by Fourier expansion;
obtaining a frequency-domain output spectrum of said digital circuit from the transfer function of said digital circuit and the Fourier-expanded input signal; and
transforming said frequency-domain output spectrum into a time-domain output waveform by an inverse Fourier transformation.

2. A storage medium storing a program for controlling a computer for analyzing noise in a digital circuit which incorporates a digital IC, a passive circuit, and a transmission line, said program comprising the steps of:
obtaining the transfer function of said digital circuit from the circuit constants of an equivalent circuit of said digital IC constituted of passive components; the circuit constants of said passive circuit; and the circuit constants of said transmission line;
expanding an input signal to be supplied to said digital circuit into a sine-wave series by Fourier expansion;
obtaining a frequency-domain output spectrum of said digital circuit from the transfer function of said digital circuit and said sine-wave series; and
transforming said frequency-domain output spectrum into a time-domain output waveform by inverse Fourier transformation.

3. An apparatus for analyzing noise in a digital circuit which incorporates a digital IC, a passive circuit, and a transmission line, said apparatus comprising:
first input means for inputting the circuit constants of an equivalent circuit of said digital IC constituted of passive components;
second input means for inputting the circuit constants of said passive circuit;
third input means for inputting the circuit constants of said transmission line;
first operation means for obtaining the transfer function of said digital circuit from said circuit constants of said equivalent circuit of said digital IC, said circuit constants of said passive circuit, and said circuit constants of said transmission line;
second operation means for expanding an input signal to be supplied to said digital circuit into a sine-wave series by a Fourier expansion;
third operation means for obtaining a frequency-domain output spectrum of said digital circuit from the transfer function of said digital circuit and said sine-wave series; and
fourth operation means for transforming said frequency-domain output spectrum into a time-domain output waveform by an inverse Fourier transformation.

4. An apparatus for analyzing noise in a digital circuit according to claim 3, further comprising:
first storing means for storing the circuit constants of respective equivalent circuits of a plurality of digital ICs,
whereby the circuit constants of a digital IC selected from said plurality of digital ICs are readable out from said first storing means to be input to said first operation means.

5. An apparatus for analyzing noise in a digital circuit according to claim 4, further comprising:
calculation means for calculating the circuit constants of said transmission line from the line width and line length of a pattern formed on a wiring board, substrate thickness, and substrate material, the calculated circuit constants being input to said first operation means.

6. An apparatus for analyzing noise in a digital circuit according to claim 3, further comprising:
calculation means for calculating the circuit constants of said transmission line from the line width and line length of a pattern formed on a wiring board, substrate thickness, and substrate material, the calculated circuit constants being input to said first operation means.

7. An apparatus for analyzing noise in a digital circuit according to any one of claims 3 to 6, further comprising:
second storing means for storing the circuit constants of a plurality of passive circuits,
whereby the circuit constants of a passive circuit selected from said plurality of passive circuits are readable out from said second storing means to be input to the first operation means.

8. An apparatus for analyzing noise in a digital circuit according to claim 7, further comprising:
a display for displaying passive circuit characteristics when selecting one of said plurality of passive circuits.

9. An apparatus for analyzing noise in a digital circuit according to claim 8, wherein said display further displays the frequency-domain output spectrum obtained by said third operation means and the time-domain output waveform obtained by said fourth operation means.

10. An apparatus for analyzing noise in a digital circuit according to claim 9, wherein said display simultaneously displays the results of a plurality of simulations performed for different transfer functions.

11. An apparatus for analyzing noise in a digital circuit according to claim 9, wherein said display further displays the impedance-frequency characteristics of said digital circuit.

12. An apparatus for analyzing noise in a digital circuit according to claim 11, wherein said display simultaneously displays the results of a plurality of simulations performed for different transfer functions.

13. An apparatus for analyzing noise in a digital circuit according to claim 7, further comprising:
a display for displaying the frequency-domain output spectrum obtained by said third operation means and the time-domain output waveform obtained by said fourth operation means.

14. An apparatus for analyzing noise in a digital circuit according to claim 13, wherein said display simultaneously displays the results of a plurality of simulations performed for different transfer functions.

15. An apparatus for analyzing noise in a digital circuit according to any one of claims 3 to 6, further comprising:
a display for displaying the frequency-domain output spectrum obtained by said third operation means and the time-domain output waveform obtained by said fourth operation means.

16. An apparatus for analyzing noise in a digital circuit according to claim 15, wherein said display simultaneously displays the results of a plurality of simulations performed for different transfer functions.

17. An apparatus for analyzing noise in a digital circuit according to claim 15, wherein said display further displays the impedance-frequency characteristics of said digital circuit.

18. An apparatus for analyzing noise in a digital circuit according to claim 17, wherein said display simultaneously displays the results of a plurality of simulations performed for different transfer functions.

19. An apparatus for analyzing noise in a digital circuit according to claim 3, further comprising:
printing means for simultaneously printing input information regarding the transfer function of said digital circuit, and the result of simulation.

20. An apparatus for analyzing noise in a digital circuit which incorporates a digital IC, a passive circuit, and a transmission line, said apparatus comprising:
a first interface which receives the circuit constants of an equivalent circuit of said digital IC constituted of passive components;
a second interface which receives the circuit constants of said passive circuit;
a third interface which receives the circuit constants of said transmission line;
a first operation unit which obtains the transfer function of said digital circuit from said circuit constants of said equivalent circuit of said digital IC, said circuit constants of said passive circuit, and said circuit constants of said transmission line;
a second operation unit which expands an input signal to be supplied to said digital circuit into a sine-wave series by a Fourier expansion;
a third operation unit which obtains a frequency-domain output spectrum of said digital circuit from the transfer function of said digital circuit and said sine-wave series; and
a fourth operation unit which transforms said frequency-domain output spectrum into a time-domain output waveform by an inverse Fourier transformation.

21. An apparatus for analyzing noise in a digital circuit according to claim 20, further comprising:
a first store containing the circuit constants of respective equivalent circuits of a plurality of digital ICs,
whereby the circuit constants of a digital IC selected from said plurality of digital ICs are readable out from said first store to be input to said first operation unit.

22. An apparatus for analyzing noise in a digital circuit according to claim 21, further comprising:
a calculation unit which determines the circuit constants of said transmission line from the line width and line length of a pattern formed on a wiring board, substrate thickness, and substrate material, the calculated circuit constants being input to said first operation unit.

23. An apparatus for analyzing noise in a digital circuit according to claim 20, further comprising:
a calculation unit which determines the circuit constants of said transmission line from the line width and line length of a pattern formed on a wiring board, substrate thickness, and substrate material, the calculated circuit constants being input to said first operation unit.

24. An apparatus for analyzing noise in a digital circuit according to any one of claims 20 to 23, further comprising:
a second store containing the circuit constants of a plurality of passive circuits,
whereby the circuit constants of a passive circuit selected from said plurality of passive circuits are readable out from said second store to be input to the first operation unit.

25. An apparatus for analyzing noise in a digital circuit according to claim 24, further comprising:
a display which displays passive circuit characteristics when selecting one of said plurality of passive circuits.

26. An apparatus for analyzing noise in a digital circuit according to claim 25, wherein said display further displays the frequency-domain output spectrum obtained by said third operation unit and the time-domain output waveform obtained by said fourth operation unit.

27. An apparatus for analyzing noise in a digital circuit according to claim 26, wherein said display simultaneously displays the results of a plurality of simulations performed for different transfer functions.

28. An apparatus for analyzing noise in a digital circuit according to claim 26, wherein said display further displays the impedance-frequency characteristics of said digital circuit.

29. An apparatus for analyzing noise in a digital circuit according to claim 28, wherein said display simultaneously displays the results of a plurality of simulations performed for different transfer functions.

30. An apparatus for analyzing noise in a digital circuit according to claim 24, further comprising:
a display which displays the frequency-domain output spectrum obtained by said third operation unit and the time-domain output waveform obtained by said fourth operation unit.

31. An apparatus for analyzing noise in a digital circuit according to claim 30, wherein said display simultaneously displays the results of a plurality of simulations performed for different transfer functions.

32. An apparatus for analyzing noise in a digital circuit according any one of claims 20 to 23, further comprising:
a display which displays the frequency-domain output spectrum obtained by said third operation unit and the time-domain output waveform obtained by said fourth operation unit.

33. An apparatus for analyzing noise in a digital circuit according to claim 32, wherein said display further displays the impedance-frequency characteristics of said digital circuit.

34. An apparatus for analyzing noise in a digital circuit according to claim 33, wherein said display simultaneously displays the results of a plurality of simulations performed for different transfer functions.

35. An apparatus for analyzing noise in a digital circuit according to claim 32, wherein said display simultaneously displays the results of a plurality of simulations performed for different transfer functions.

36. An apparatus for analyzing noise in a digital circuit according to claim 20, further comprising:
a printer which is capable of simultaneously printing input information regarding the transfer function of said digital circuit, and the result of simulation.

37. A method of enabling a user to select a passive circuit, said passive circuit being included in a digital circuit along with a digital IC and a transmission line, comprising the steps of:
supplying said user with a program for analyzing noise in said digital circuit, on the basis of circuit constants of said digital IC, said transmission line, and said passive circuit;
and supplying said user with circuit constants of a plurality of passive circuits,
thereby enabling said user to select a passive circuit from among said plurality of passive circuits on the basis of an analysis result of said program.

38. A method according to claim 37, wherein said program is supplied to said user on a storage medium.

39. A method according to claim 37, wherein said program is supplied by making said program available for downloading over a network.

40. A method according to claim 37, wherein said program comprises the steps of:
obtaining the transfer function of said digital circuit from the circuit constants of an equivalent circuit of said digital IC constituted of passive components; the circuit constants of said passive circuit; and the circuit constants of said transmission line;
expanding an input signal to be supplied to said digital circuit into a sine-wave series by Fourier expansion;
obtaining a frequency-domain output spectrum of said digital circuit from the transfer function of said digital circuit and said sine-wave series; and
transforming said frequency-domain output spectrum into a time-domain output waveform by inverse Fourier transformation.

41. A method according to claim 40, wherein said passive components are filters.

42. A method according to claim 37, wherein said circuit constants are supplied to said user on a storage medium.

43. A method according to claim 37, wherein said circuit constants are supplied to said user by making them available for downloading over a network.
